(19) United States
(12) Patent Application Publication
(10) Pub. No.: US 2025/0203870 A1
(43) Pub. Date: Jun. 19, 2025

(54) INTEGRATED CIRCUIT DEVICE AND METHOD OF MANUFACTURING THE SAME

(71) Applicant: United Microelectronics Corp., Hsinchu (TW)

(72) Inventors: Chih-Hao Pan, Kaohsiung City (TW); Chao-Sheng Cheng, Taichung City (TW); Po-Jui Chiang, Changhua County (TW); Pei Lun Jheng, Tainan City (TW); Hsin-Chieh Lin, Kaohsiung City (TW); Wei-Xun Chen, Nantou County (TW); Sheng Jhe Gao, Tainan City (TW); Yu-Kai Wang, Taoyuan City (TW); Wei Chung Peng, New Taipei City (TW)

(73) Assignee: United Microelectronics Corp., Hsinchu (TW)

(21) Appl. No.: 18/415,624

(22) Filed: Jan. 17, 2024

(30) Foreign Application Priority Data
Dec. 15, 2023 (TW) 112148956

(51) Int. Cl. H10B 43/40; G11C 16/10; G11C 16/14; H10B 41/40

(52) U.S. Cl. CPC H10B 43/40; H10B 41/40; G11C 16/10; G11C 16/14

(57) ABSTRACT

A method for manufacturing an integrated circuit device includes the following steps. A first gate structure of a medium voltage device (MVP) having a first conductivity type and a second gate structure of a high voltage device (HVP) having the first conductivity type, a third gate structure of a medium voltage device (MVN) having a second conductivity type, and a fourth gate structure of a high voltage device (HVN) having the second conductivity type are respectively formed in first to fourth regions of a substrate. First lightly doped drain regions (PLDD) having the first conductivity type are formed in the substrate respectively in the first, second and fourth regions aside the first, second and fourth gate structures. Second lightly doped drain regions (NLDD) having the second conductivity type are formed in the substrate respectively in the third and fourth regions aside the third and fourth gate structures.

### CROSS-REFERENCE TO RELATED APPLICATION

This application claims the priority benefit of Taiwan application serial no. 112148956, filed on Dec. 15, 2023. The entirety of the above-mentioned patent application is hereby incorporated by reference herein and made a part of the specification.

### BACKGROUND

### Technical Field

The present disclosure relates to an integrated circuit device and a method of manufacturing the same.

### Description of Related Art

With the development of technology, many modern electronic devices can include semiconductor devices with different operating voltages, such as medium voltage devices and high voltage devices, etc. Medium voltage devices and high voltage devices are very critical devices for memory devices such as flash memory. A high voltage is required for programming and erasing of flash memory. Therefore, increasing the breakdown voltage of an integrated circuit device is a very important topic.

### SUMMARY

The present disclosure provides an integrated circuit device and a manufacturing method thereof, in which the breakdown voltage of a medium voltage device can be increase without reducing the breakdown voltage of a high voltage device.

In an embodiment of the present disclosure, a method for manufacturing an integrated circuit device includes the following steps. A first gate structure of a medium voltage device (MVP) having the first conductivity type, a second gate structure of a high voltage device (HVP) having the first conductivity type, a third gate structure of a medium voltage device (MVN) having a second conductivity type and a fourth gate structure of a high voltage device (HVN) having the second conductivity type are respectively formed in the first region to the fourth region of the substrate. Multiple first LDD regions (PLDD) having the first conductivity type are formed in the substrate beside the first gate structure, the second gate structure and the fourth region in the first region, the second region and the fourth region, respectively. Multiple second LDD regions (NLDD) having the second conductivity type are formed in the substrate beside the second gate structure and the fourth gate structure in the third region and the fourth region, respectively.

In an embodiment of the present disclosure, an integrated circuit device includes a medium voltage device having a first conductivity type, a high voltage device having a first conductivity type, a medium voltage device having a second conductivity type, and a high voltage device having a second conductivity type. The first gate structure of the medium voltage device having the first conductivity type, the second gate structure of the high voltage device having the first conductivity type, the third gate structure of the medium voltage device having the second conductivity type and the fourth gate structure of the high voltage device having the second conductivity type are respectively disposed in the first region, second region, third region and fourth region of the substrate. Multiple first LDD regions having the first conductivity type are disposed in the first region and the second region. Multiple second LDD regions having the second conductivity type are disposed in the third region. Multiple third LDD regions having the third conductivity type are disposed in the fourth region. The dopant concentration of the second LDD regions is greater than the dopant concentration of the third LDD regions.

Based on the above, the integrated circuit device according to an embodiment of the present disclosure can increase the breakdown voltage of a medium voltage device without reducing the breakdown voltage of a high voltage device.

In the method of manufacturing the integrated circuit device according to an embodiment of the present disclosure, without adding a photomask, the breakdown voltage of a medium voltage device can be increase without reducing the breakdown voltage of a high voltage device.

### BRIEF DESCRIPTION OF THE DRAWINGS

FIG. 1A to FIG. 1K are cross-sectional views of a method of manufacturing an integrated circuit device according to an embodiment of the present disclosure.

FIG. 2A to FIG. 2D are cross-sectional views of a method of manufacturing an integrated circuit device according to another embodiment of the present disclosure.

### DESCRIPTION OF THE EMBODIMENTS

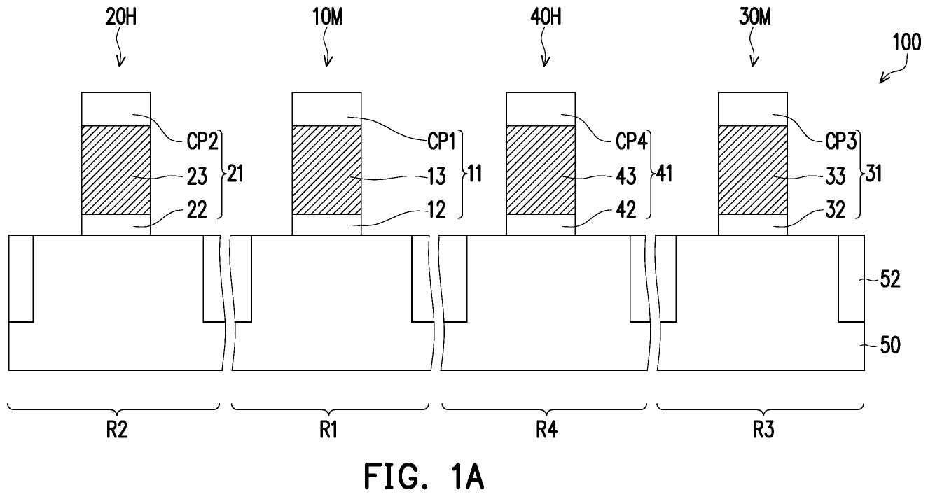

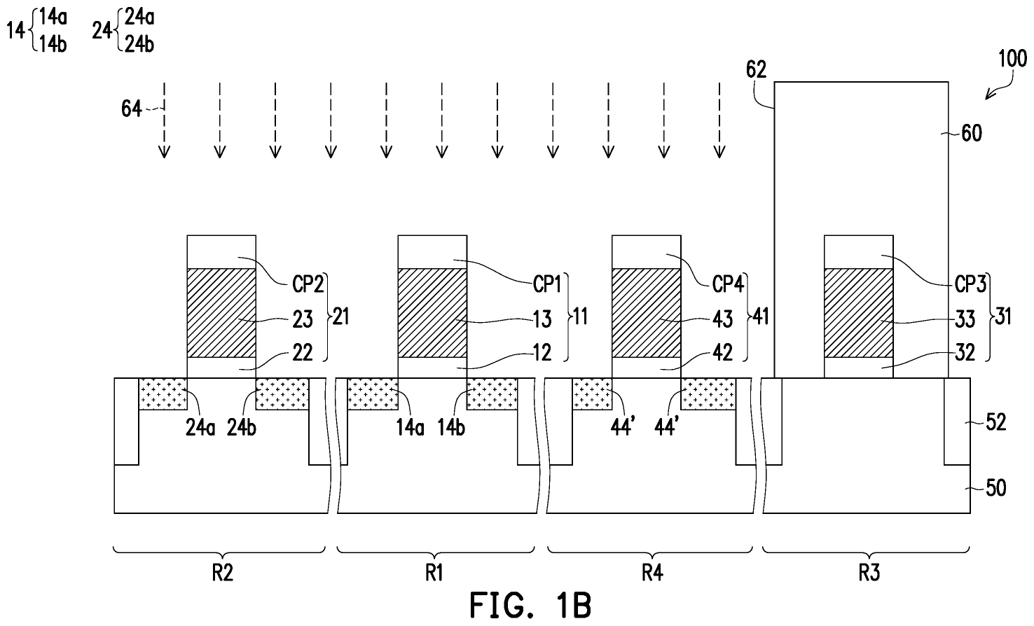

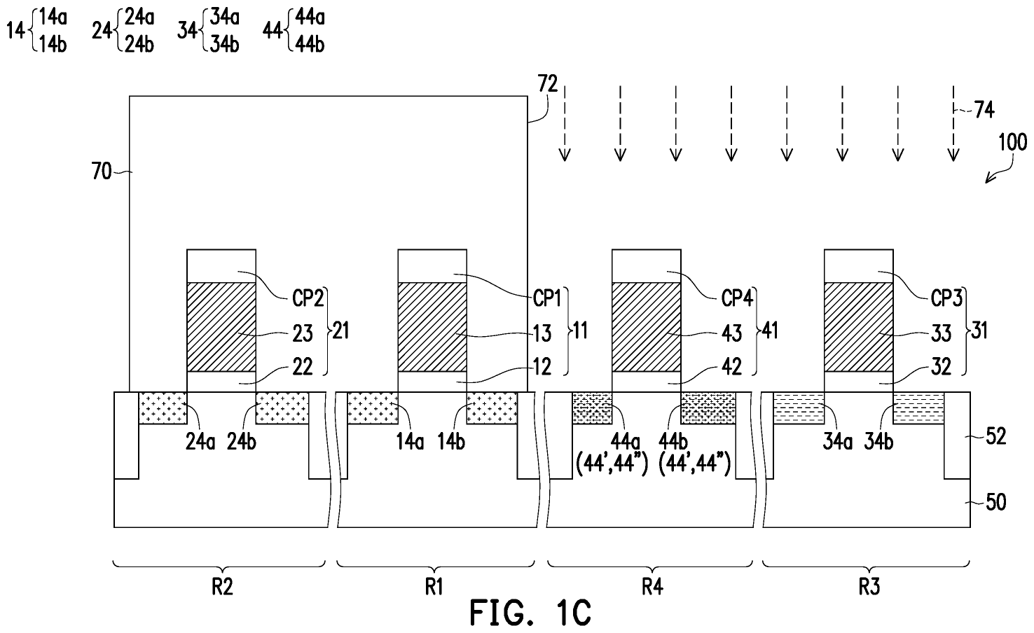

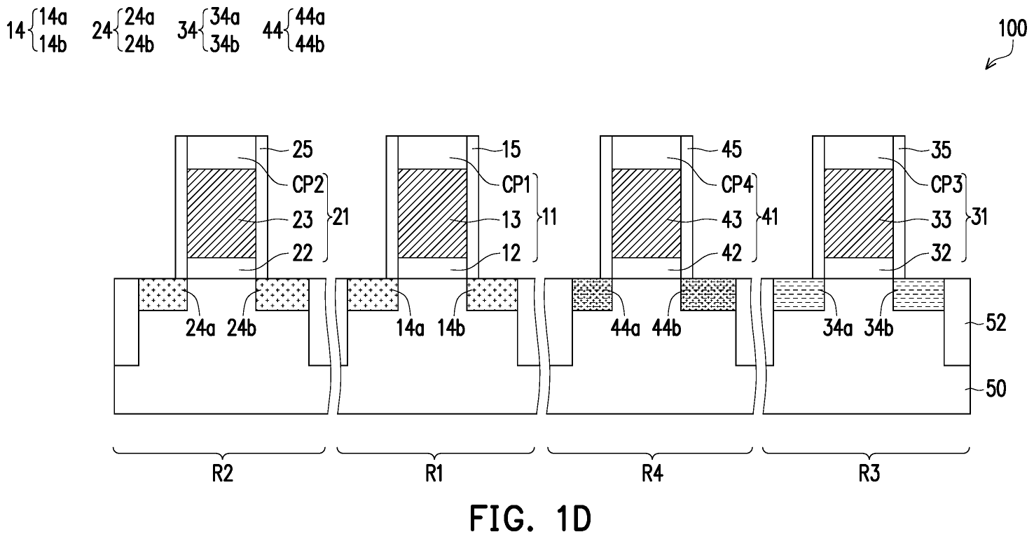

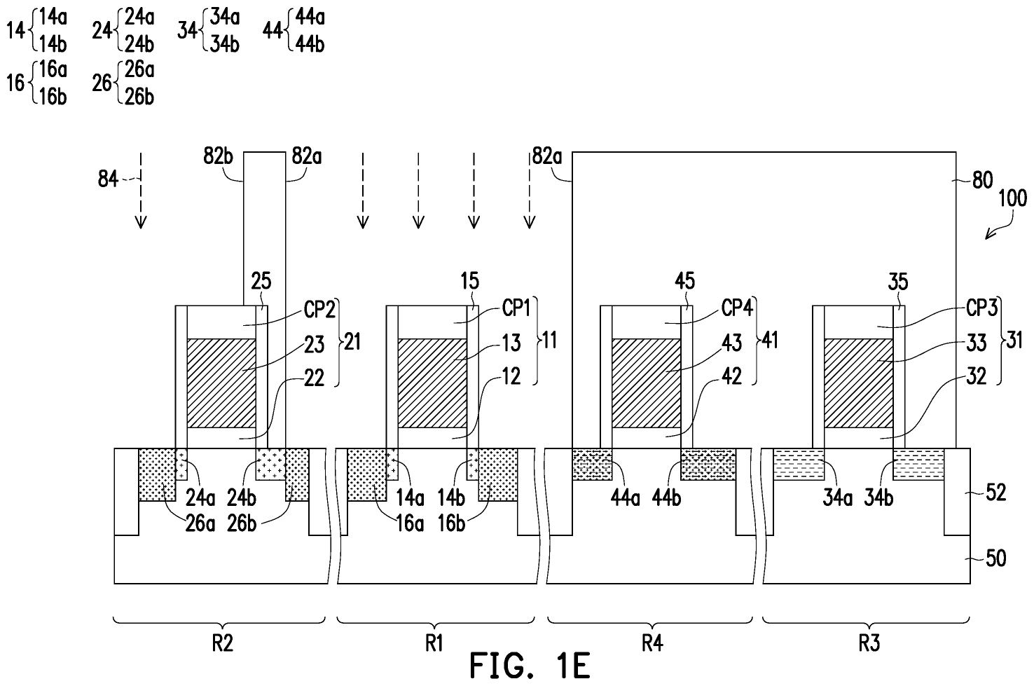

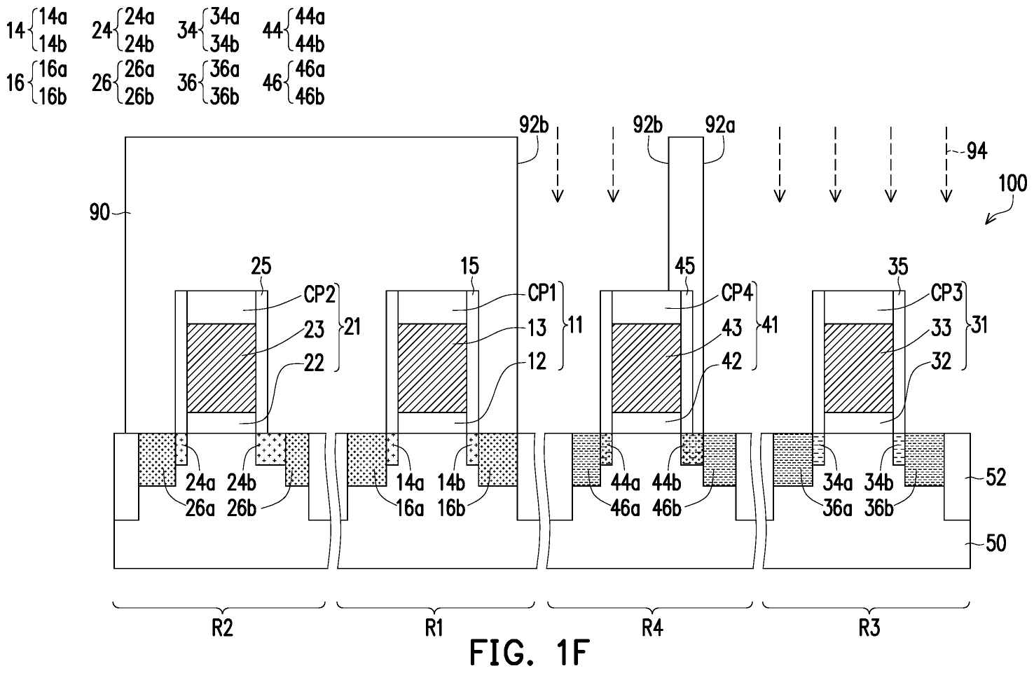

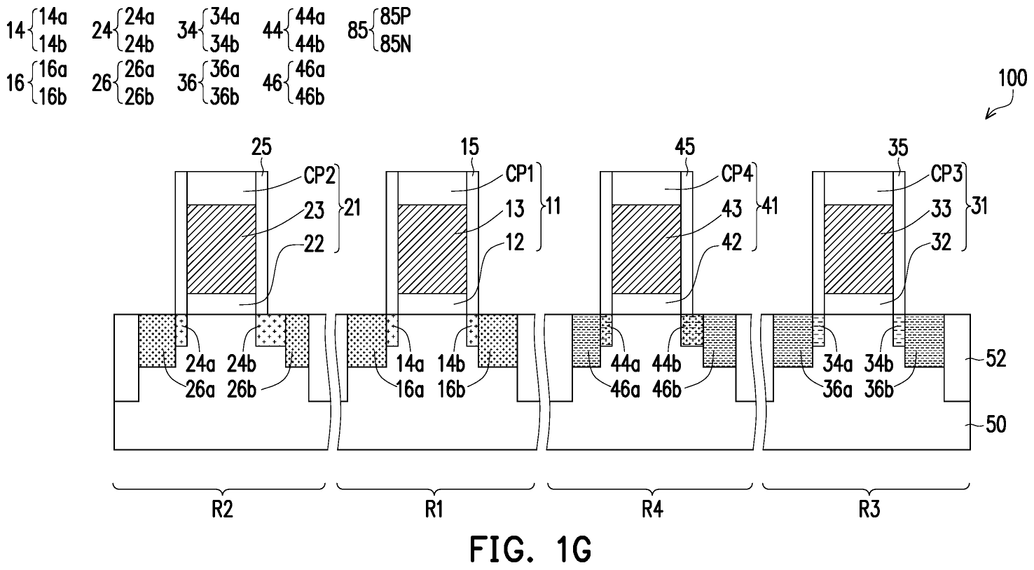

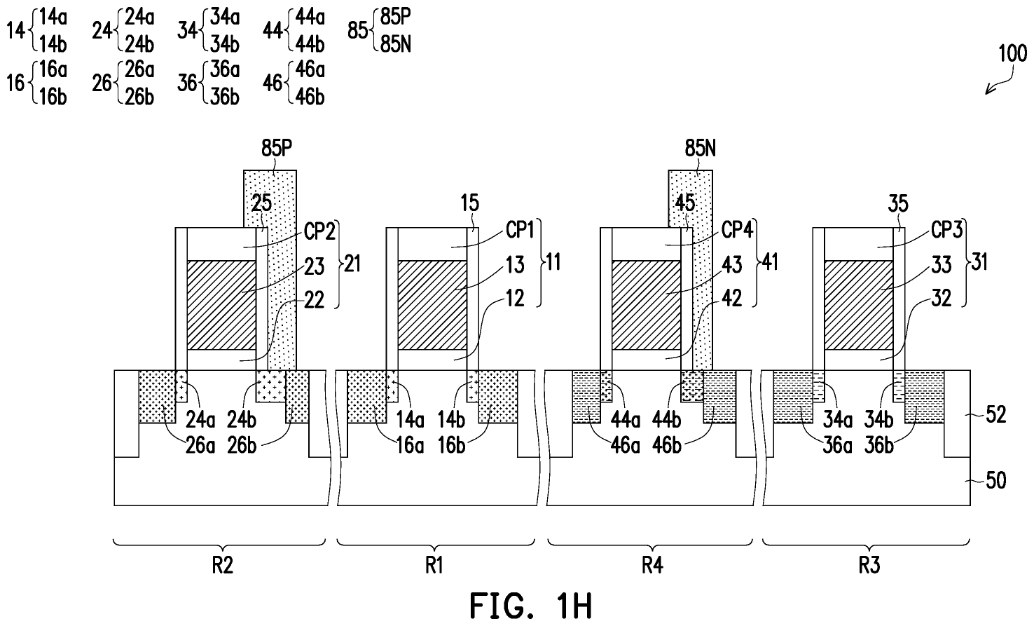

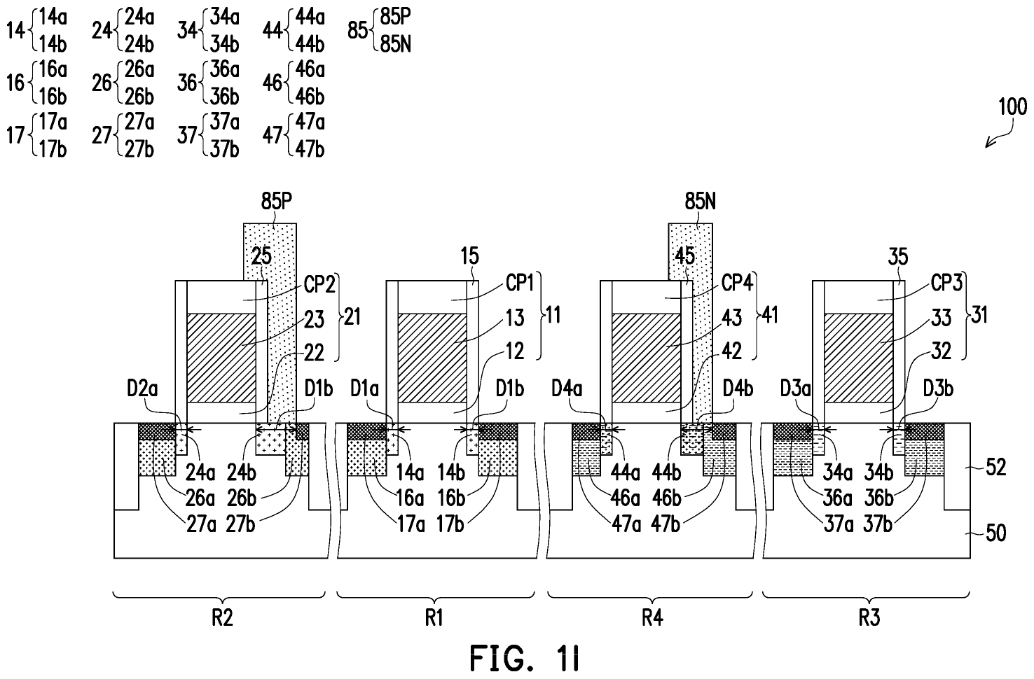

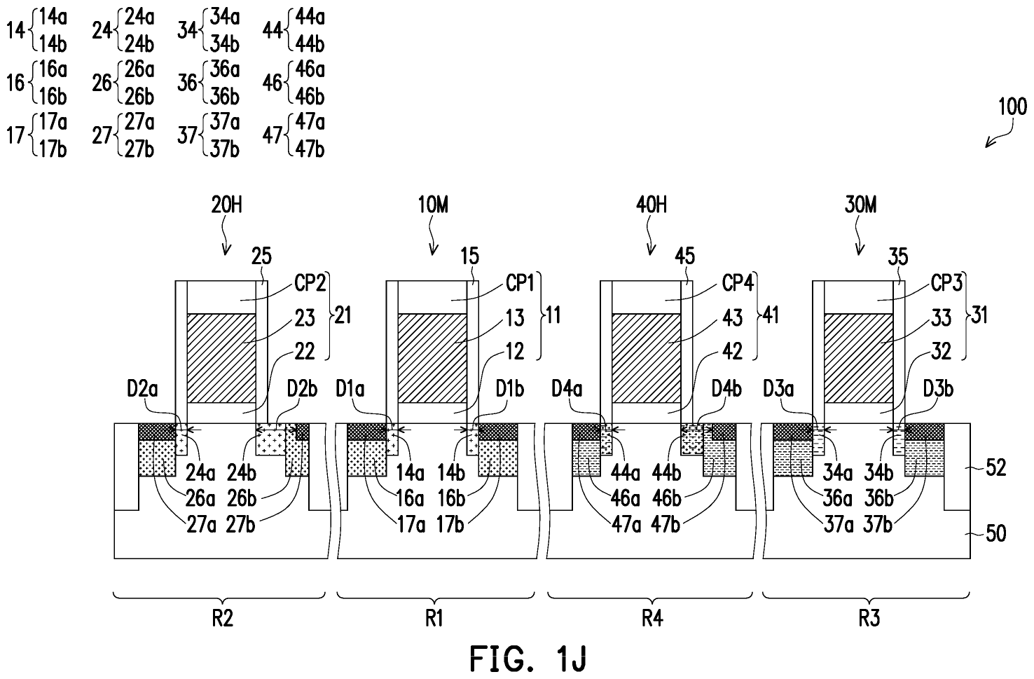

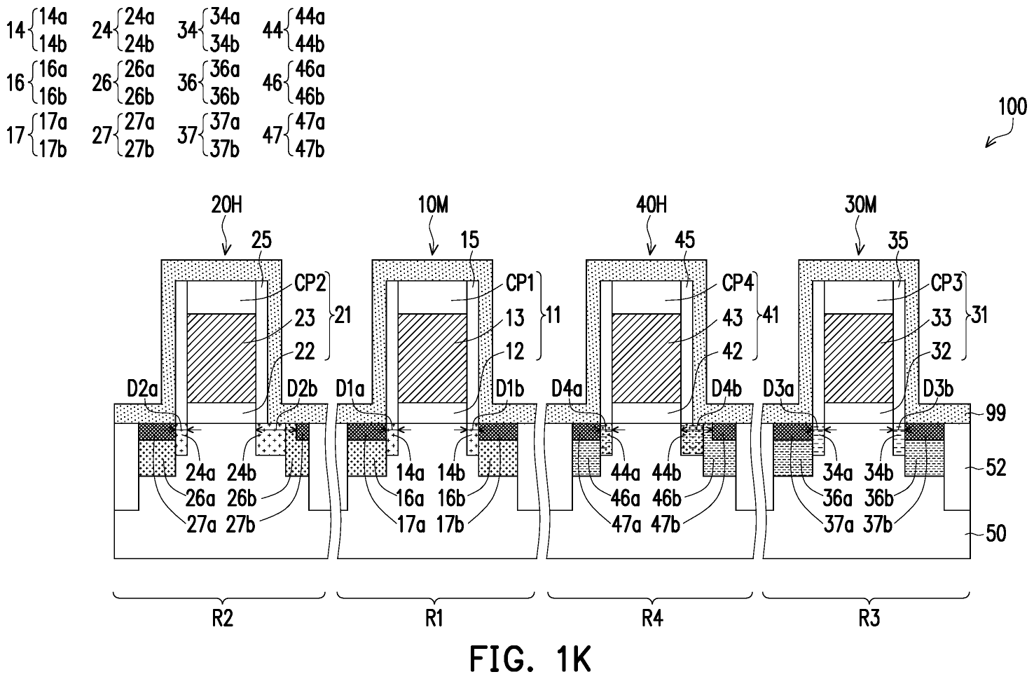

Referring to FIG. 1A, a method of manufacturing an integrated circuit device 100 includes providing a substrate 50. The substrate 50 includes a semiconductor substrate, such as silicon substrate. Isolation structures 52 are formed in the substrate 50, so that the substrate 50 may include a first region R1, a second region R2, a third region R3 and a fourth region R4. The isolation structures 52 may include shallow trench isolation structures. The shallow trench isolation structures include insulating materials such as silicon oxide, silicon nitride, or a combination thereof.

Referring to FIG. 1A, a first gate structure 11 of a medium voltage device 10M having a first conductivity type, a second gate structure 21 of a high voltage device 20H having the first conductivity type, a third gate structure 31 of a medium voltage device 30M having a second conductivity type, and a fourth gate structure 41 of a high voltage device 40H having the second conductivity type are respectively formed in the first region R1 to the fourth region R4 of the substrate 50. In some embodiments, the first conductivity type includes P type; and the second conductivity type includes N type. The first gate structure 11, the second gate structure 21, the third gate structure 31 and the fourth gate structure 41 may respectively include gate dielectric layers 12, 22, 32, 42, gate conductive layers 13, 23, 33, 43 and cap layers CP1, CP2, CP3, CP4. The gate dielectric layers 12, 22, 32, and 42 may include silicon oxide, high dielectric constant materials, or a combination thereof. The gate conductive layers 13, 23, 33, and 43 may include polysilicon. The cap layers CP1, CP2, CP3 and CP4 may include silicon oxide, silicon nitride or a combination thereof.

Referring to FIG. 1B, in the embodiment of the present disclosure, multiple first lightly doped drain (LDD) regions 14 and 24 having the first conductivity type are formed in the first region R1 and the second region R2, and multiple first LDD regions 44′ having the first conductivity type are formed in the fourth region R4. Multiple first LDD regions 14, 24, and 44′ may be formed using the method described below. First, a first mask layer 60 is formed on the substrate 50. The first mask layer 60 has a first opening 62 that exposes the first region R1, the second region R2 and the fourth region R4. Then, a first ion implantation process 64 is performed, using the first mask layer 60 as an implantation mask, so as to form multiple first LDD regions 14, 24, and 44′ having the first conductivity type beside the first gate structure 11, the second gate structure 21 and the fourth gate structure 41 in the first region R1, the second region R2 and the fourth region R4. The ion concentration of the first ion implantation process 64 may be about 2×10¹³/cm³. Afterwards, the first mask layer 60 is removed, as shown in FIG. 1B. The first conductivity type ions (dopants) implanted in the first ion implantation process 64 include boron or boron trifluoride.

Referring to FIG. 1C, multiple second LDD regions 34 and 44″ having the second conductivity type are formed in the third region R3 and the fourth region R4. Multiple second LDD regions 34, 44″ may be formed before multiple first LDD regions 14, 24, 44′ are formed, or may be formed after multiple first LDD regions 14, 24, 44′ are formed. Multiple second LDD regions 34, 44″ may be formed using the method described below. First, a second mask layer 70 is formed on the substrate 50. The second mask layer has a second opening 72 that exposes the third region R3 and the fourth region R4. A second ion implantation process 74 is performed, using the second mask layer 70 as an implantation mask, so as to form multiple second LDD regions 34, 44″ having the second conductivity type in the substrate 50 beside the third gate structure 31 and the fourth gate structure 41 in the third region R3 and the fourth region R4. The second conductivity type ions (dopants) implanted in the second ion implantation process 74 may include phosphorus or arsenic. Afterwards, the second mask layer 70 is removed, as shown in FIG. 1C.

Referring to FIG. 1C, in this embodiment, the ion concentration of the second ion implantation process 74 is greater than the ion concentration of the first ion implantation process 64. The ion concentration of second ion implantation process 74s may be about 5×10¹³/cm³. The ion concentration of the second ion implantation process 74 is 2 to 3 times that of the first ion implantation process 64. In the fourth region R4, first conductivity type ions in the first LDD regions 44′ are partially neutralized (or called compensated/offset) by second conductivity type ions in the second LDD regions 44″, so as to form multiple third LDD regions 44 having the second conductivity type. The un-neutralized second conductivity type ion concentration (final concentration) of the third LDD regions 44 in the fourth region R4 is lower than the second conductivity type ion concentration of the second LDD regions 34 in the third region R3. In this way, the breakdown voltage of the medium voltage device 30M having the second conductivity type according to an embodiment of the present disclosure can be increased. For the high voltage device 40H having the second conductivity type, the second conductivity type ions are partially neutralized by the first conductivity type ions. Therefore, even if the ion concentration of the second ion implantation process 74 is 2 to 3 times that of the first ion implantation process 64, the breakdown voltage of the high voltage device 40H having the second conductivity type is not reduced.

Referring to FIG. 1D, spacers 15, 25, 35, and 45 are formed on the sidewalls of the first gate structure 11, the second gate structure 21, the third gate structure 31, and the fourth gate structure 41. The spacers 15, 25, 35, and 45 may have a single-layer or multi-layer structure. The spacers 15, 25, 35 and 45 may include silicon oxide, silicon nitride or a combination thereof.

Referring to FIG. 1E, multiple first heavily doped regions 16 and 26 having the first conductivity type are formed in the substrate 50 in the first region R1 and the second region R2. Multiple first heavily doped regions 16 and 26 may be formed using the method described below. A third mask layer 80 is formed on the substrate 50, covering the third region R3 and the fourth region R4, and partially covering the second gate structure 21, the spacers 25 and the first LDD regions 24b in the second region R2. The third mask layer 80 has third openings 82a and 82b. The third opening 82a exposes the substrate 50, the first gate structure 11, the spacers 15 and the first LDD regions 14a and 14b in the first region R1. The third opening 82b exposes the second gate structure 21, the remaining part of the spacers 25 and the first LDD regions 24a in the second region R2. A third ion implantation process 84 is performed, using the third mask layer 80 and the spacers 15 and 25 as implantation masks, so as to form multiple first heavily doped regions 16 and 26 having the first conductivity types in the substrate 50 in the first region R1 and the second region R2.

Referring to FIG. 1F, the third mask layer 80 is removed. Next, multiple second heavily doped regions 36 and 46 having the second conductivity type are formed in the substrate 50 in the third region R3 and the fourth region R4. Multiple second heavily doped regions 36 and 46 may be formed using the method described below. A fourth mask layer 90 is formed on the substrate 50. The fourth mask layer 90 covers the first region R1 and the second region R2, and partially covers the fourth gate structure 41, the spacers 45 and the third LDD region 44b in the fourth region R4. The fourth mask layer 90 has fourth openings 92a and 92b. The fourth opening 92a exposes the substrate 50, the third gate structure 31, the spacers 35 and the second LDD regions 34a and 34b in the third region R3. The fourth opening 92b exposes the fourth gate structure 41, the remaining part of the spacers 45 and the third LDD regions 44a in the fourth region R4. A fourth ion implantation process 94 is performed, using the fourth mask layer 90 and spacers 35 and 45 as implantation masks, so as to form multiple second heavily doped regions 36 and 46 having the second conductivity type in the substrate 50 in the third region R3 and fourth region R4.

Referring to FIG. 1G, the fourth mask layer 90 is removed. The multiple first LDD regions 14a and 14b left in the first region R1 have substantially the same width. The multiple first LDD regions 24a and 24b left in the second region R2 have different widths. The top surfaces of the first LDD regions 14a and 14b left in first region R2 are covered by the spacers 15. The top surfaces of the first LDD regions 24a left in the second region R2 are covered by the spacers 25. The top surface of the first part of the first LDD region 24b left in the second region R2 is covered by the spacers 25. The top surface of the second part of the first LDD region 24b left in the second region R2 is not covered by the spacers 25. The multiple second LDD regions 34a and 34b left in the third region R3 have substantially the same width. The top surfaces of the second LDD region 34a and 34b left in the third region R3 are covered by spacers 35. The multiple third LDD regions 44a and 44b left in the fourth region R4 have different widths. The top surface of the third LDD region 44a left in the fourth region R4 is covered by spacers 45. The top surface of the first part of the third LDD region 44a left in the fourth region R4 is covered by spacers 45. The top surface of the second part of the third LDD region 44b left in the fourth region R4 is not covered by the spacers 45.

Referring to FIG. 1H, a blocking layer 85 is formed on the substrate 50. The blocking layer 85 includes blocking layers 85P and 85N. The blocking layer 85P covers part of the second gate structure 21, part of the spacers 25, part of the first LDD region 24b and part of the first heavily doped region 26b. The blocking layer 85N covers part of the fourth gate structure 41, part of the spacers 45, part of the third LDD region 44b and part of the second heavily doped region 46b. The blocking layer 85 includes an insulating material such as silicon oxide, silicon nitride, or a combination thereof. The blocking layer 85 may be formed by forming a blocking material on the substrate 50, and then patterning the blocking material into the blocking layer 85 through photolithography and etching processes.

Referring to FIG. 1I, a self-aligned metal silicide process is performed to form multiple metal silicide layers 17, 27, 37, 47. The multiple metal silicide layers 17, 27, 37, and 47 may include nickel silicide (NiSi), nickel platinum silicide (NiPtSi), or cobalt silicide (CoSi).

Referring to FIG. 1J, the blocking layer 85 is removed. The metal silicide layers 17a and 17b in the first region R1 have equal or substantially the same width or area. The metal silicide layers 27a and 27b in the second region R2 have different widths. The metal silicide layers 37a and 37b in the third region R3 have equal or substantially the same width. The metal silicide layers 47a and 47b in the fourth region R4 have different widths.

The distance D1b between the metal silicide layer 17b and the first gate structure 11 in the first region R1 is substantially the same with the distance D1a between the metal silicide layer 17a and the first gate structure 11 in the first region R1. The distance D2a between the metal silicide layers 27a and the second gate structure 21 and the distance D2b between the metal silicide layers 27b and the second gate structure 21 are different in the second region R2. In this example, the distance D2b between the metal silicide layer 27b and the second gate structure 21 in the second region R2 is greater than the distance D2a between the metal silicide layer 27a and the second gate structure 21 in the second region R2. The distance D3b between the metal silicide layer 37b and the third gate structure 31 in the third region R3 is substantially the same with the distance D3a between the metal silicide layer 37a and the third gate structure 31 in the third region R3. The distance D4a between the metal silicide layer 47a and the fourth gate structure 41 and the distance D4b between the metal silicide layer 47b and the fourth gate structure 41 in the fourth region R4 are different. In this embodiment, the distance D4b between the metal silicide layer 47b and the fourth gate structure 41 in the fourth region R4 is greater than the distance D4a between the metal silicide layer 47a and the fourth gate structure 41 in the fourth region R4.

The distance D2b between the metal silicide layer 27b and the second gate structure 21 in the second region R2 is greater than the distance D1b between the metal silicide layer 17b and the first gate structure 11 in the first region R1. The distance D4b between the metal silicide layer 47b and the fourth gate structure 41 in the fourth region R4 is greater than the distance D3b between the metal silicide layer 37b and the third gate structure 31 in the third region R3.

The metal silicide layers 17a and 17b in the first region R1 are respectively in contact with the spacers 15 on the sidewalls of the first gate structure 11. The metal silicide layer 27a in the second region R2 is in contact with the spacers 25 on the sidewalls of the second gate structure 21. There is a non-zero distance between the metal silicide layer 27b and the spacers 35 on the sidewalls of the second gate structure 21 in the second region R2. The metal silicide layers 37a and 37b in the third region R3 are respectively in contact with the spacers 35 of the sidewalls of the third gate structure 31. The metal silicide layer 47a in the fourth region R4 is in contact with the spacers 45 on the sidewalls of the fourth gate structure 41. There is a non-zero distance between the metal silicide layer 47b and the spacers 45 on the sidewalls of the fourth gate structure 41 in the fourth region R4.

The multiple metal silicide layers 17a and 17b almost completely cover the multiple first heavily doped regions 16a and 16b in the first region R1. The metal silicide layer 27a almost completely covers the first heavily doped region 26a in the second region R2. In the second region R2, the metal silicide layer 27b partially covers the first heavily doped region 26b, and part of the first heavily doped region 26b is not covered by the metal silicide layer 27b. The multiple metal silicide layers 37a and 37b almost completely cover the multiple first heavily doped regions 36a and 36b in the third region R3. The metal silicide layer 47a almost completely covers the second heavily doped region 46a in the fourth region R4. In the fourth region R4, the metal silicide layer 47b partially covers the second heavily doped region 46b, and part of the second heavily doped region 46b is not covered by the metal silicide layer 47b.

The areas of the top surfaces of the first LDD regions 24a and 24b and the areas of the top surfaces of the first heavily doped regions 26a and 26b that are not covered by the metal silicide layers 27a and 27b in the second region R2 are greater than the areas of the top surfaces of the first LDD regions 14a and 14b that are not covered by the metal silicide layers 17a and 17b in the first region R1. The areas of the top surfaces of the third LDD regions 44a and 44b and the areas of the top surfaces of the second heavily doped region 44a and 44b that are not covered by the metal silicide layers 47a and 47b in the fourth region R4 is greater than the areas of the top surfaces of the second LDD regions 34a and 34b that are not covered by the metal silicide layers 37a and 37b in the third region R3.

In this embodiment, as compared with the medium voltage device 10M having the first conductivity type, the high voltage device 20H having the first conductivity type is more asymmetrical. As compared with the medium voltage device 30M having the second conductivity type, the fourth gate structure 41 of the high voltage device 40H having the second conductivity type is more asymmetrical. However, the embodiments of the present disclosure are not limited thereto.

Referring to FIG. 1K, a stop layer 99 is formed on the substrate 50. The stop layer 99 includes silicon nitride, silicon oxynitride, or a combination thereof. The stop layer 99 covers the first gate structure 11, the second gate structure 21, the third gate structure 31, the fourth gate structure 41, the spacers 15, 25, 35, 45, and the metal silicide layers 17, 27, 37, 47. In addition, the top surface of the first LDD region 24b and the top surface of the first heavily doped region 26b in the second region R2, and the top surface of the third LDD region 44b and the top surface of the second heavily doped region 46b in the fourth region R4 are covered by and in contact with the stop layer 99.

In the integrated circuit device 100 of the above embodiment, as compared with the medium voltage device 10M having the first conductivity type, the high voltage device 20H having the first conductivity type is more asymmetrical. As compared with the medium voltage device 30M having the second conductivity type, the fourth gate structure 41 of the high voltage device 40H having the second conductivity type is more asymmetrical. However, the embodiments of the present disclosure are not limited thereto.

More specifically, the first LDD regions 14a and 14b and the first heavily doped regions 16a and 16b of the medium voltage device 10M having the first conductivity type are substantially symmetrical. The second LDD regions 34a and 34b and the second heavily doped regions 36a and 36b of the medium voltage device 30M having the second conductivity type are substantially symmetrical. The first LDD regions 24a and 24b and the first heavily doped regions 26a and 26b of the high voltage device 20H having the first conductivity type are asymmetric. The third LDD regions 44a and 44b and the second heavily doped regions 46a and 46b of the high voltage device 40H having the second conductivity type are asymmetric. The dopant concentration of the second LDD regions 34a and 34b of the medium voltage device 30M having the second conductivity type is increased, while the dopant concentration of the third LDD regions 44a and 44b of the high voltage device 40H having the second conductivity type is lower than that of the second LDD regions 34a and 34b. Thereby, the chip area can be saved and the performance of the integrated circuit device 100 can be improved. In some embodiments, the breakdown voltage of the medium voltage device 10M having the first conductivity type can be greater than about 8 volts; the breakdown voltage of high voltage devices 20H having the first conductivity type can be greater than about 13.5 volts; the breakdown voltage of 30M of medium voltage devices having the second conductivity type can be greater than about 10 volts; the breakdown voltage of the high voltage device 40H having the second conductivity type can be greater than about 14.5 volts.

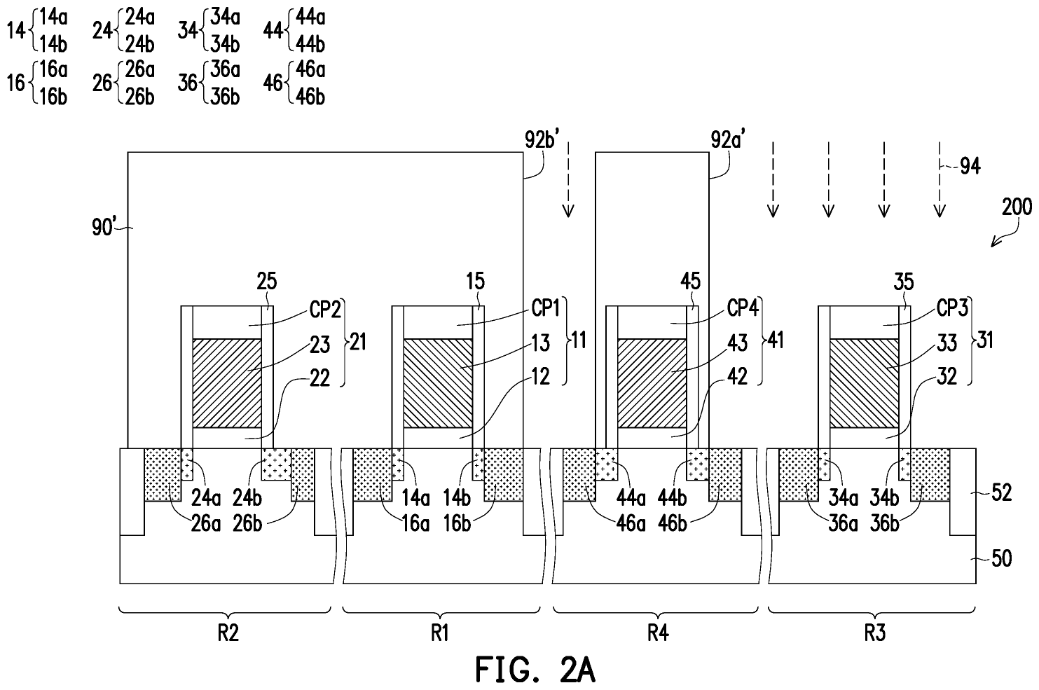

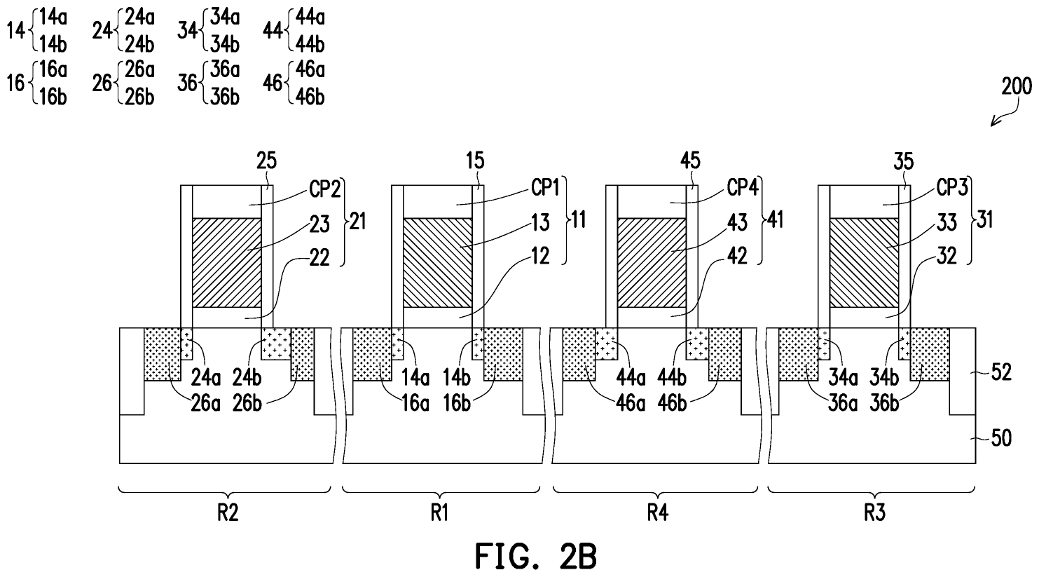

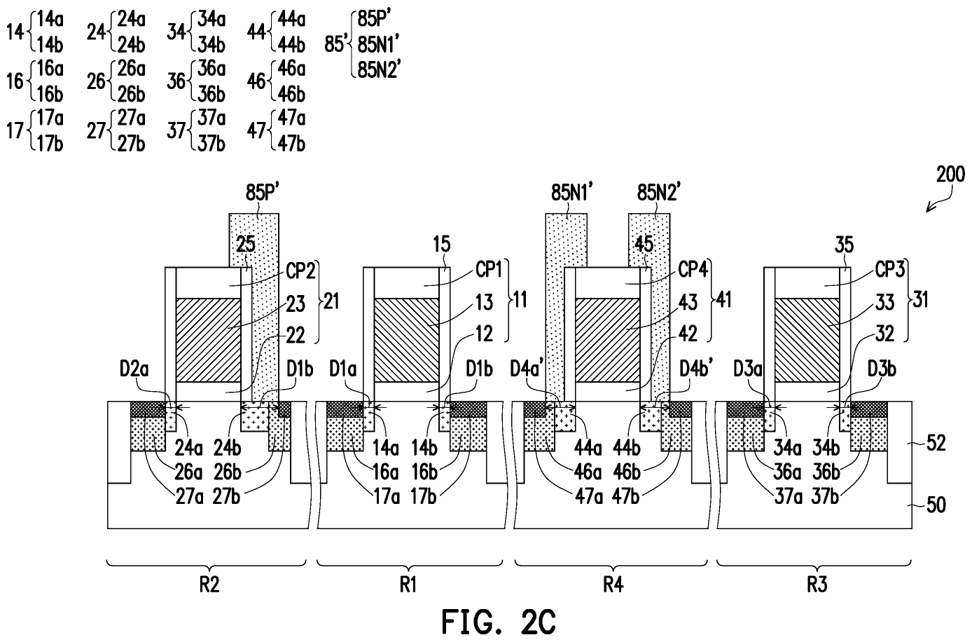

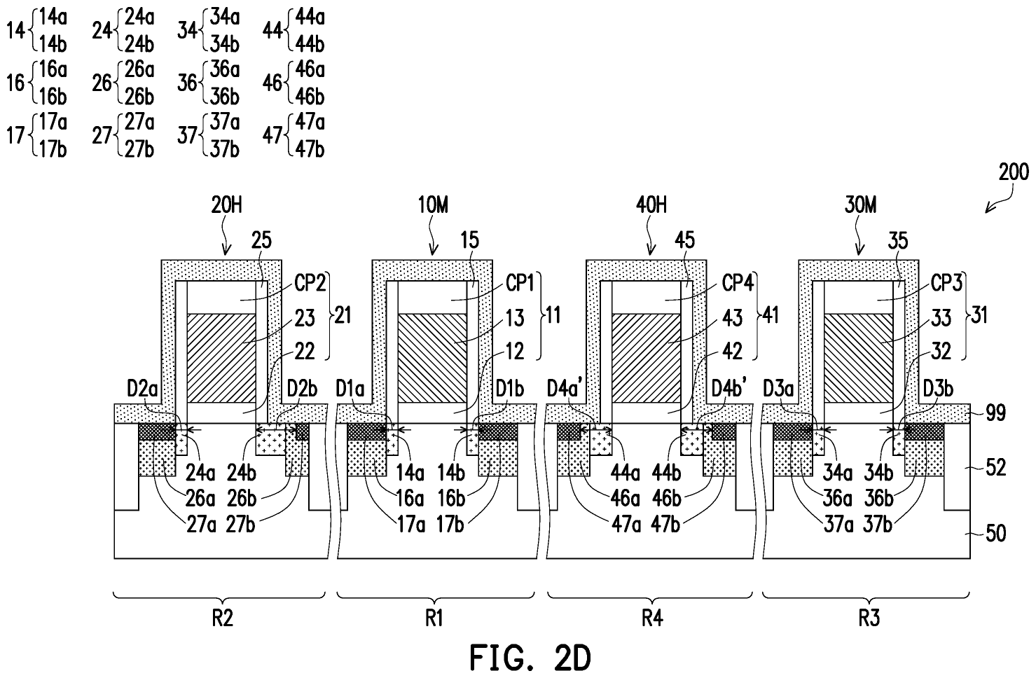

FIG. 2A to FIG. 2D are cross-sectional views of a method of manufacturing an integrated circuit device according to another embodiment of the present disclosure.

Referring to FIG. 2A, according to the method described above with reference to FIG. 1A to FIG. 1E, a first gate structure 11 of a medium voltage device 10M having a first conductivity type, a second gate structure 21 of a high voltage device 20H having the first conductivity type, a third gate structure 31 of a medium voltage device 30M having a second conductivity type and a fourth gate structure 41 of a high voltage device 40H having the second conductivity type, multiple first LDD regions 14, 24, multiple second LDD regions 34, multiple third LDD regions 44, multiple spacers 15, 25, 35, 45, and multiple first heavily doped regions 16, 26 are formed on the substrate 50.

Referring to FIG. 2A, a fourth mask layer 90′ is formed on the substrate 50. The fourth mask layer 90′ covers the first region R1 and the second region R2, and covers the fourth gate structure 41 and the spacers 45 in the fourth region R4, and partially covers the third LDD regions 44a and 44b. The fourth mask layer 90′ has fourth openings 92a′ and 92b′. The fourth opening 92a′ exposes the substrate 50, the third gate structure 31, the spacers 35, the second LDD regions 34a and 34b in the third region R3, and the third LDD region 44b in the fourth region R4. The fourth opening 92b′ exposes the third LDD region 44a in the fourth region R4. A fourth ion implantation process 94 is performed, using the fourth mask layer 90′ as an implantation mask, so as to form second heavily doped regions 36 and 46 having the second conductivity type in the substrate 50 in the third region R3 and the fourth region R4.

Referring to FIG. 2B, the fourth mask layer 90′ is removed. The multiple first LDD regions 14a and 14b in first region R1 have substantially the same width and are covered by spacers 15. The multiple first LDD regions 24a and 24b have different widths in the second region R2. The top surface of the first LDD region 24a is covered by the spacers 25 in the second region R2. The top surface of the first part of the first LDD region 24b is covered by spacers 25 in the second region R2. The top surface of the second part of the first LDD region 24b is not covered by the spacers 25 in the second region R2. The multiple second LDD regions 34a and 34b have substantially the same width and are covered by the spacers 35 in the third region R3. In the fourth region R4, the multiple third LDD regions 44a and 44b have substantially the same width, and part of them is covered by the spacers 45, and the other part of them is not covered by the spacers 45.

Referring to FIG. 2C, a blocking layer 85′ is formed on the substrate 50. The blocking layer 85′ includes blocking layers 85P′, 85N1′ and 85N2′. The blocking layer 85P′ covers part of the second gate structure 21, part of the spacers 25, part of the first LDD region 24b and part of the first heavily doped region 26b. The blocking layers 85N1′ and 85N2′ respectively cover parts of the fourth gate structure 41, parts of the spacers 45, parts of the third LDD regions 44a and 44b, and parts of the second heavily doped regions 44a and 46b. The blocking layer 85′ includes an insulating material such as silicon oxide, silicon nitride or a combination thereof. The blocking layer 85′ is formed by forming a blocking material on the substrate 50, and then patterning the blocking material into the blocking layer 85′ through photolithography and etching processes.

Referring to FIG. 2C and FIG. 2D, multiple metal silicide layers 17, 27, 37, and 47 are formed on the first heavily doped regions 16, 26 and the second heavily doped regions 36, 46 that are not covered by the blocking layer 85′. Afterwards, the blocking layer 85′ is removed, and a stop layer 99 is formed on the substrate 50.

Referring to FIG. 2D, in the integrated circuit device 200 of this embodiment, the medium voltage device 10M having the first conductivity type, the medium voltage device 30M having the second conductivity type, and the high voltage device 40H of the fourth gate structure 41 having the second conductivity type are more symmetrical, respectively. The high voltage device 20H having the first conductivity type is more asymmetrical. In more details, in the integrated circuit device 200, the first LDD regions 14a and 14b and the first heavily doped regions 16a and 16b of the medium voltage device 10M having the first conductivity type are substantially symmetrical. The second LDD regions 34a and 34b and the second heavily doped regions 36a and 36b of the medium voltage device 30M having the second conductivity type are substantially symmetrical. The third LDD regions 44a and 44b and the second heavily doped regions 46a and 46b of the high voltage device 40H having the second conductivity type are substantially symmetrical. The first LDD regions 24a and 24b and the first heavily doped regions 26a and 26b of the high voltage device 20H having the first conductivity type are asymmetric. The medium voltage device 10M having the first conductivity type, the high voltage device 20H having the first conductivity type, the medium voltage devices 30M having the second conductivity type are substantially the same as the medium voltage device 10M having the first conductivity type, the high voltage device 20H having the first conductivity type, and the medium voltage device 30M having the second conductivity type in the integrated circuit device 100 of the above embodiment, so the description will not be repeated herein, and only the high voltage device 40H having the second conductivity type will be described below.

In the integrated circuit device 200 of this embodiment, the top surfaces of the third LDD regions 44a and 44b of the high voltage device 40H having the second conductivity type are covered and in contact with the spacers 45 and the stop layer 99.

Parts of the top surfaces of second heavily doped regions 46a and 46b are covered by and in contact with the stop layer 99. Metal silicide layers 47a and 47b are formed in the second heavily doped regions 46a and 46b. The metal silicide layers 47a and 47b have substantially the same width. The distance D4a′ between the metal silicide layer 47a and the fourth gate structure 41 and distance D4b′ between the metal silicide layer 47b and the fourth gate structure 41 are substantially the same. There is a non-zero distance between the metal silicide layers 47a and 47b and the spacers 45. The metal silicide layer 47a partially covers the second heavily doped region 46a, and part of the second heavily doped region 46a is not covered by the metal silicide layer 47a. The metal silicide layer 47b partially covers the second heavily doped region 46b, and part of the second heavily doped region 46b is not covered by the metal silicide layer 47b. The areas of the top surfaces of the third LDD regions 44a and 44b and the top surfaces of the second heavily doped regions 47a and 47b that are not covered by the metal silicide layers 47a and 47b in the fourth region R4 are greater than the areas of the top surfaces of the second LDD regions 34a and 34b that are not covered by the metal silicide layers 37a and 37b in the third region R3.

Based on the above, in the embodiments of the present disclosure, a higher dose is implanted to form second LDD regions of a medium voltage device having a second conductivity type and a high voltage device having the second conductivity type, so as to increase the breakdown voltage of the medium voltage device having the second conductivity type. However, the dose in the second LDD regions of the high voltage device having the second conductivity type is too high, which causes the breakdown voltage to drop. In the embodiments of the present disclosure, during the first ion implantation process of forming the first LDD regions of the medium voltage device having the first conductivity type and the high voltage device having the first conductivity type, the first LDD regions are simultaneously formed in the substrate for the high voltage device having the second conductivity type, so as to neutralize (or compensate/offset) the second ions in the second LDD regions to form third LDD regions, thus preventing the breakdown voltage drop of the high voltage device having the second conductivity type.

In addition, in the embodiment of the present disclosure, the high voltage device having the first conductivity type and the high voltage device having the second conductivity type can be designed to be asymmetrical according to the needs; or the high voltage device having the first conductivity type can be designed to be asymmetrical, while the high voltage device having the second conductivity type can be designed to be asymmetrical. Then, the chip area is reduced while maintaining the performance.

What is claimed is:

1. A method of manufacturing an integrated circuit device, comprising:
forming a first gate structure of a medium voltage device having a first conductivity type, a second gate structure of a high voltage device having the first conductivity type, and a third gate structure of a medium voltage device having a second conductivity type, and a fourth gate structure of a high voltage device having the second conductivity type respectively in first region to fourth regions of a substrate;
forming a plurality of first lightly doped drain (LDD) regions having the first conductivity type in the substrate respectively beside the first gate structure, the second gate structure and the fourth gate structure; and
forming a plurality of second LDD regions having the second conductivity type in the substrate respectively beside the third gate structure and the fourth gate structure.

2. The method of claim 1, wherein forming the plurality of first LDD regions having the first conductivity type comprises:
forming a first mask layer on the substrate, the first mask layer having a first opening exposing the first region, the second region and the fourth region;
performing a first ion implantation process using the first mask as an implantation mask, so as to form the plurality of first LDD regions having the first conductivity type in the substrate in the first region, the second region and the fourth region; and
removing the first mask layer.

3. The method of claim 2, wherein forming the plurality of second LDD regions having the second conductivity type comprises:
forming a second mask layer on the substrate, and the second mask layer having a second opening exposing the third region and the fourth region;
performing a second ion implantation process using the second mask as an implantation mask, so as to form the plurality of second LDD regions having the second conductivity type in the substrate in the third region and the fourth region; and
removing the second mask layer.

4. The method of claim 3, wherein the first conductivity type comprises P type; and the second conductivity type comprises N type.

5. The method of claim 4, wherein an ion concentration of the second ion implantation process is greater than an ion concentration of the first ion implantation process.

6. The method of claim 4, wherein an ion concentration of the second ion implantation process is 2 to 3 times an ion concentration of the first ion implantation process.

7. The method of claim 4, wherein:
forming a plurality of third LDD regions by neutralizing ions of the plurality of first LDD regions and ions of the plurality of second LDD regions in the fourth region.

8. The method of claim 7, wherein forming a plurality of first heavily doped regions having the first conductivity type comprises:
forming a third mask layer on the substrate, covering the third region and the fourth region, and partially covering one of the plurality of first LDD regions in the second region;
performing a third ion implantation process using the third mask as an implantation mask, so as to form the plurality of first heavily doped regions having the first conductivity type in the substrate in the first region and the second region; and
remove the third mask layer,
wherein the plurality of first LDD regions in the second region have different widths.

9. The method of claim 8, wherein forming a plurality of second heavily doped regions having the second conductivity type comprises:
forming a fourth mask layer on the substrate, covering the first region and the second region, and partially covering one of the plurality of third LDD regions in the fourth region;
performing a fourth ion implantation process is performed using the fourth mask as an implantation mask, so as to form the plurality of second heavily doped regions having the second conductivity type in the substrate in the third region and the fourth region; and
remove the fourth mask layer,
wherein the plurality of third LDD regions in the fourth region have different widths.

10. The method of claim 9, further comprising:
forming a plurality of metal silicide layers on the plurality of first LDD regions and the plurality of second LDD regions, wherein
distances from the plurality of metal silicide layers to the second gate structure in the second region are different; and
distances from the plurality of metal silicide layers to the fourth gate structure in the fourth region are different.

11. The method of claim 8, wherein forming a plurality of second heavily doped regions having the second conductivity type comprises:
forming a fourth mask layer on the substrate, covering the first region and the second region, and partially covering the plurality of third LDD regions in the fourth region;
performing a fourth ion implantation process using the fourth mask as an implantation mask, so as to form the plurality of second heavily doped regions having the second conductivity type in the substrate in the third region and the fourth region; and
removing the fourth mask layer,
wherein first parts of the third LDD regions left in the fourth region are covered by spacers on sidewalls of the third gate structure, the remaining second parts of the third LDD regions are not covered by the spacers on the sidewalls of the third gate structure.

12. An integrated circuit device, comprising:
a first gate structure of a medium voltage device having a first conductivity type, a second gate structure of a high voltage device having the first conductivity type, a third gate structure of a medium voltage device having a second conductivity type, and a fourth gate structure of a high voltage device having the second conductivity type, respectively disposed in a first region, a second region, a third region and a fourth region of a substrate;
a plurality of first LDD regions having the first conductivity type, disposed in the first region and the second region;
a plurality of second LDD regions having the second conductivity type, disposed in the third region; and
a plurality of third LDD regions having the third conductivity type, disposed in the fourth region,
wherein a dopant concentration of the second LDD regions is greater than a dopant concentration of the third LDD regions.

13. The integrated circuit device of claim 12, wherein:
the dopant concentration of the second LDD region is greater than a dopant concentration of the first LDD regions.

14. The integrated circuit device of claim 12, further comprising:
a plurality of first heavily doped regions having the first conductivity type, with the same dopant concentration, disposed in the substrate in the first region and the second region; and
a plurality of second heavily doped regions having the second conductivity type, with the same dopant concentration, disposed in the substrate in the third region and the fourth region.

15. The integrated circuit device of claim 14, further comprising:
a plurality of metal silicide layers, disposed on the plurality of first LDD regions in the first region and the second region, on the plurality of second LDD regions in the third region and on the plurality of third LDD regions in the fourth region.

16. The integrated circuit device of claim 15, wherein:
the metal silicide layers are in contact with spacers on sidewalls of the first gate structure in the first region;
distances between the metal silicide layers and spacers on sidewalls of the second gate structure are different in the second region;
the metal silicide layers are in contact with spacers on sidewalls of the third gate structure in the third region; and
distances between the metal silicide layers and spacers on sidewalls of the fourth gate structure are different in the fourth region.

17. The integrated circuit device of claim 15, wherein a distance between one of the metal silicide layers and the second gate structure in the second region is greater than a distance between the metal silicide layer and the first gate structure in the first region; and
a distance between one of the metal silicide layers and the fourth gate structure in the fourth region is greater than a distance between the metal silicide layer and the third gate structure in the third region.

18. The integrated circuit device of claim 17, further comprising:
a stop layer, disposed on the substrate, wherein the stop layer covers the first gate structure, the second gate structure, the third gate structure, the fourth gate structure, the spacers and the metal silicide layers, and covers a top surface of one of the first LDD regions and a top surface of one of the first heavily doped regions in the second region, and a top surface of one of the third LDD regions and a top surface of one of the second heavily doped regions in the fourth region.

19. The integrated circuit device of claim 15, wherein:
the metal silicide layers are in contact with spacers on sidewalls of the first gate structure in the first region;
distances between the metal silicide layers and spacers on sidewalls of the second gate structure in the second region are different;
the metal silicide layers are in contact with spacers on sidewalls of the third gate structure in the third region; and
distances between the metal silicide layers and spacers on sidewalls of the fourth gate structure in the fourth region are the same.

20. The integrated circuit device of claim 19, further comprising:
a stop layer, disposed on the substrate, wherein the stop layer covers the first gate structure, the second gate structure, the third gate structure, the fourth gate structure, the spacers, and the metal silicide layers, and covers a top surface of one of the first LDD regions and a top surface of one of the first heavily doped regions in the second region, and top surfaces of the third LDD regions and top surfaces of the second heavily doped regions in the fourth region.
